(19) United States
(12) Patent Application Publication
(10) Pub. No.: US 2005/0258488 A1
(43) Pub. Date: Nov. 24, 2005

(54) Serially connected thin film transistors and fabrication methods thereof

(75) Inventors: Shih-Chang Chang, Hsinchu (TW); Chun-Hsiang Fang, Yilan Hsien (TW); Yaw-Ming Tsai, Taichung Hsien (TW)

Correspondence Address: LIU & LIU, 444 S. FLOWER STREET, SUITE 1750, LOS ANGELES, CA, 90071, US

(73) Assignee: Toppoly Optoelectronics Corp.

(21) Appl. No.: 11/189,479

(22) Filed: Jul. 26, 2005

Related U.S. Application Data
(63) Continuation-in-part of application No. 10/960,183, filed on Oct. 6, 2004.
(63) Continuation-in-part of application No. 10/850,980, filed on May 20, 2004.
Application No. 10/960,183 is a continuation-in-part of application No. 10/833,487, filed on Apr. 27, 2004.
Application No. 10/850,980 is a continuation-in-part of application No. 10/833,487, filed on Apr. 27, 2004.

(30) Foreign Application Priority Data
Aug. 19, 2004 (TW) 93124928

(51) Int. Cl. H01L 31/0376

(52) U.S. Cl. 257/347

(57) ABSTRACT

Serially connected thin film transistor (TFT) structure include an active layer shared by an N-type TFT region and a P-type TFT region. A contact hole is formed in an N/P junction between the N-type TFT region and the P-type TFT region and conductive carriers within an N-doped region at one end can be electrically connected to a P-doped region at the other end by a conductive layer formed in the contact hole, without formation of depletion regions at the N/P junction. Moreover, the N-type TFT region or the P-type TFT region is formed using the exposed gate insulating layer in mask regions on both sides of the gate electrode as ion implanting masks and lightly doped drain regions and source/drain regions are also simultaneously formed.

### CROSS REFERENCE TO RELATED APPLICATION

The present invention is a continuation-in-part (CIP) application of the prior application Ser. No. 10/960,183 filed on Oct. 6, 2004 and the prior application Ser. No. 10/850,980 filed on May 20, 2004, which are themselves CIPs of prior application Ser. No. 10/833,487, filed on Apr. 27, 2004.

### BACKGROUND

The present invention relates to a thin film transistor (TFT) technology, and more particularly to serially connected N-type and P-type thin film transistors and fabrication methods thereof.

Thin film transistors (TFTs) are used in a variety of integrated circuits, and in particular, as a switching device in each pixel area and each driving circuit area of active matrix liquid crystal displays (AMLCD). According to the materials used, a TFT is classified as either an amorphous silicon TFT or a polysilicon TFT. Compared with the amorphous TFT, the polysilicon TFT has the advantages of high carrier mobility, high integration of driving circuits, small leakage current and higher speed operation, and is often applied to high-speed operation applications. One of the major problems of these TFTs is the OFF-state leakage current, which causes charge loss and high standby power dissipation. Seeking to solve this problem, conventional lightly doped drain (LDD) regions have been used to reduce the drain junction field, thereby reducing the leakage current. With the increased integration of designed circuits, however, improvement to circuit surfaces reduction in the peripheral region has become a critical issue in increasing resolution of the AMLCD. In addition, photo misalignment and critical dimension variation can occur in the LDD region during photolithography.

FIGS. 1A to 1H are cross sections showing a conventional method for forming serially connected N-type and P-type TFTs.

In FIG. 1A, a substrate 10 including an N-type TFT region I and a P-type TFT region II is provided. A first polysilicon layer 12I, a first gate insulating layer 14I and a first gate electrode 16I are formed in the N-type TFT region I. A second polysilicon layer 12II, a second gate insulating layer 14II and a second gate electrode 16II are formed in the P-type TFT region II.

Next, in FIG. 1B, a first photoresist layer 18 is formed to cover the P-type TFT region II and a N-type light doping process 20 is then performed on the N-type TFT region I, using the first gate electrode 16I as an implant mask, thus forming N⁻ doped regions 12Iₐ in the first polysilicon layer 12I at both sides of the first gate electrode 16I. The first photoresist layer 18 is then removed.

Next, in FIG. 1C, a second photoresist layer 22 is formed to cover the N-type TFT region I and a P-type light doping process 24 is then performed to the P-type TFT region II, using the second gate electrode 16II as an implant mask, thus forming P⁻ doped regions 12IIₐ in the second polysilicon layer 12II at both sides of the second gate electrode 16II. The second photoresist layer 22 is then removed.

Next, in FIG. 1D, first sidewall spacers 26I and second sidewall spacers 26II are respectively formed on sidewalls of the first gate electrode 16I and the second gate electrode 16II thorough sequential deposition, photolithography and dry etching of an insulating layer. The first sidewall spacers 26I and the second sidewall spacers 26II respectively cover a portion of the underlying N⁻ doped region 12Iₐ and the P⁻ doped region 12IIₐ.

Next, a third photoresist layer 28 is formed to cover the P-type TFT region II and an N-type heavy doping process 30 is performed on the N-type TFT region I, using the first gate electrode 16I and the first sidewall spacers 26I as an implant mask, thus forming N⁺ doped regions 12I_{b}, 12I_{c} in the N⁻ doped regions 12Iₐ at both sides of the first sidewall spacers 26I, as shown in FIG. 1E. The third photoresist layer 28 is then removed. An N-type TFT is thus formed, wherein the N⁺ doped region 12I_{b} serves as source diffusion region, the N⁺ doped region 12I_{c} serves as drain diffusion region, and the N⁻ doped regions 12Iₐ serves as LDD regions.

A fourth photoresist layer 32 is then formed to cover the N-type TFT region I. A P-type heavy doping process 34 is performed on the P-type TFT region II to form P⁺ doped regions 12II_{b}, 12II_{c} in the P⁻ doped regions 12IIₐ at both sides of the second sidewall spacers 26II, as shown in FIG. 1F. The fourth photoresist layer 32 is then removed. A P-type TFT is thus essentially formed, wherein the P⁺ doped region 12II_{b} serves as source diffusion region, the P⁺ doped region 12II_{c} serves as drain diffusion region and the P-doped regions 12IIₐ serves as LDD regions.

As shown in FIG. 1G, an interlayer dielectric layer 36 is then formed on the N-type TFT and the P-type TFT. A first contact hole 38A, a second contact hole 38B, a third contact hole 38C and a fourth contact hole 38D are then formed in the interlayer dielectric layer 36 through sequential photolithography and etching thereof. The first contact hole 38A exposes the N⁺ doped region 12I_{b}, the second contact hole 38B exposes the N⁺ doped region 12I_{c}, the third contact hole 38C exposes the P⁺ doped region 12II_{b}, and the fourth contact hole 38D exposes the P⁺ doped region 12II_{c}.

Finally, as shown in FIG. 1H, a plurality of contact plugs 40A, 40B, 40C, 40D, and a first source conductive layer 40S₁, a second source conductive layer 40S₂ and a drain conductive layer 40E are formed by sequential deposition, photolithography and etching of a conductive layer. The conductive layer filled in the first contact hole 38A serves as the first contact plug 40A for electrically connecting the first source conductive layer 40S₁ and the N⁺ doped region 12I_{b}. The conductive layer filled in the third contact hole 38C serves as the third contact plug 40C for electrically connecting the second source conductive layer 40S₂ and the P⁺ doped region 12II_{b}. The conductive layer filled in the second contact hole 38B and the fourth contact hole 38D respectively serves as the second contact plug 40B and the fourth contact plug 40D for electrically connecting the drain conductive layer 40E and the N⁺ doped region 12I_{c} and the P⁺ type doped region 12II_{c} simultaneously.

Potential disadvantages of the conventional serially connected N-type and P-type TFTs are described below.

The first polysilicon layer 12I and the second polysilicon layer 12II are formed into two separate island structures for preventing carrier transfer due to a depletion region formed in a junction of the N⁺ doped region 12I_{c} and the P⁺ type doped region 12II_{c} (hereinafter as N/P junction). Thus, the second contact plug 40B and the fourth contact plug 40D must be sequential fabricated to electrically connect the drain conductive layer 40D may be required. The described series structure affects pixel resolution of an AMLCD due to larger surfaces required, which is undesirable when utilizing a higher level designed integration circuit, for example a digital analog converter (DAC).

In addition, patterning of the spacers 26I and 26II requires precise control in the steps of the described method to ensure that the location and the size of the LDD region are correct. Moreover, twice ion implantation steps cause serious variation in the LDD regions due to the photo misalignment during exposure. Moreover, the described method is complex, suffers low product yield and controlling the length of the LDD regions is difficult.

### SUMMARY

The present invention is directed to a thin film transistor structure, comprising two TFTs of different types, having a contiguous active layer. In one aspect, a first doped region of a first type in the first TFT is contiguous to a second doped region of a second type in the second TFT.

Some embodiments comprise a substrate with a first conductive type thin film transistor and a second conductive type thin film transistor respectively overlying thereover, wherein the first conductive type is different from the second conductive type and a source/drain region of the first and second conductive type thin film transistors are contiguous, forming a depletion region at a junction therebetween. A dielectric layer overlies the first and second TFTs. A contact hole forms in the dielectric layer to expose the depletion region at the junction of the first and second TFTs. A conductive layer forms in the contact hole to electrically connect the depletion region at the junction of the first and second TFTs. A method for fabricating serially connected TFTs is also provided. Some embodiments of fabricating serially connected TFTs comprises a substrate having a first conductive type TFT region and a second conductive type TFT region provided. An active layer is formed on the substrate. An insulating layer is formed on the substrate, covering the active layer. A first conductive layer is formed on the gate insulating layer. An etching is performed to define the first conductive layer to a first gate electrode and a second gate electrode and the insulating layer to a first gate insulating layer and a second gate insulating layer. A first ion implantation is performed on the first conductive type thin film transistor region to form a first channel region and a first conductive type doped region therein. A second ion implantation is performed on the second conductive type thin film transistor region to form a second channel region and a second conductive type doped region therein, wherein a junction is formed between the first conductive type doped region and the second conductive type doped region. An interlayer dielectric layer is formed to cover the first conductive type TFT region and the second conductive type TFT region. A contact hole is formed in the interlayer dielectric layer to exposing a junction between a first conductive type doped region in the first conductive type TFT region and a second conductive type doped region in the second conductive type TFT region. A second conductive layer is formed in the contact hole to electrically connect the first conductive type heavily doped region and the second conductive type heavily doped region.

### DESCRIPTION OF THE DRAWINGS

The present invention can be more fully understood by reading the subsequent detailed description and examples with references made to the accompanying drawings, wherein:

FIGS. 1A˜1H are cross sections of a conventional method for forming serially connected N-type and P-type TFTs;

FIGS. 2A˜2F are cross sections of a method for forming serially connected polysilicon TFTs according to the an embodiment of the invention;

FIG. 3 is a schematic layout of serially connected polysilicon TFTs according to an embodiment of the invention;

FIG. 4 is a cross section of serially connected polysilicon TFTs according to another embodiment of the invention;

FIGS. 5A˜5B are cross sections of serially connected polysilicon TFTs according to yet another embodiment of the invention;

FIG. 6 is a schematic view illustrating an embodiment of a display device of the present invention, incorporating an embodiment of a thin film transistor structure of the invention; and

FIG. 7 is a schematic diagram illustrating an electronic device incorporating an embodiment of a display device of the invention.

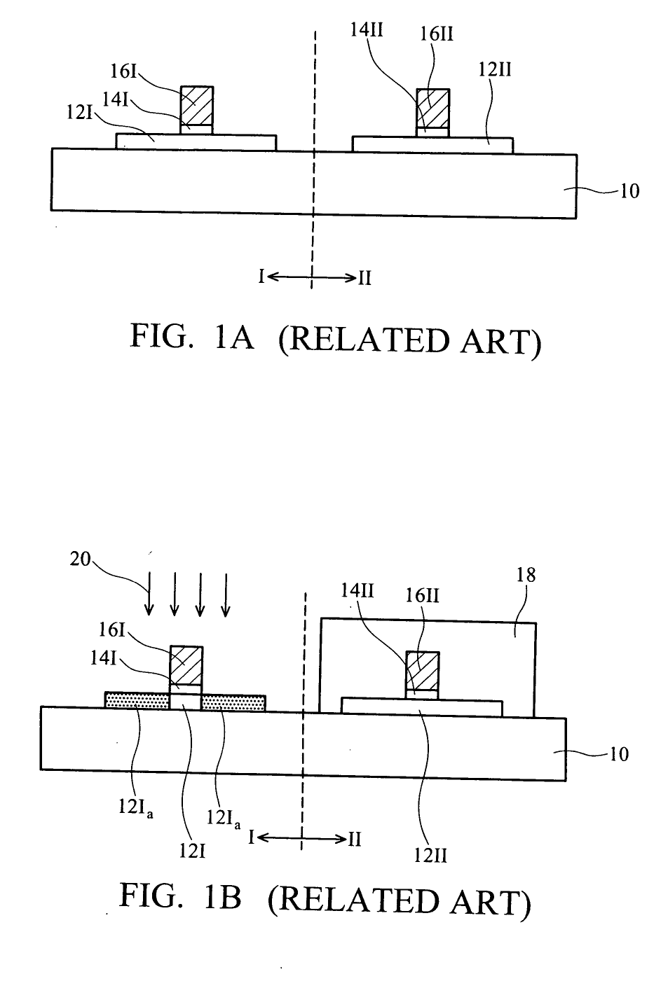

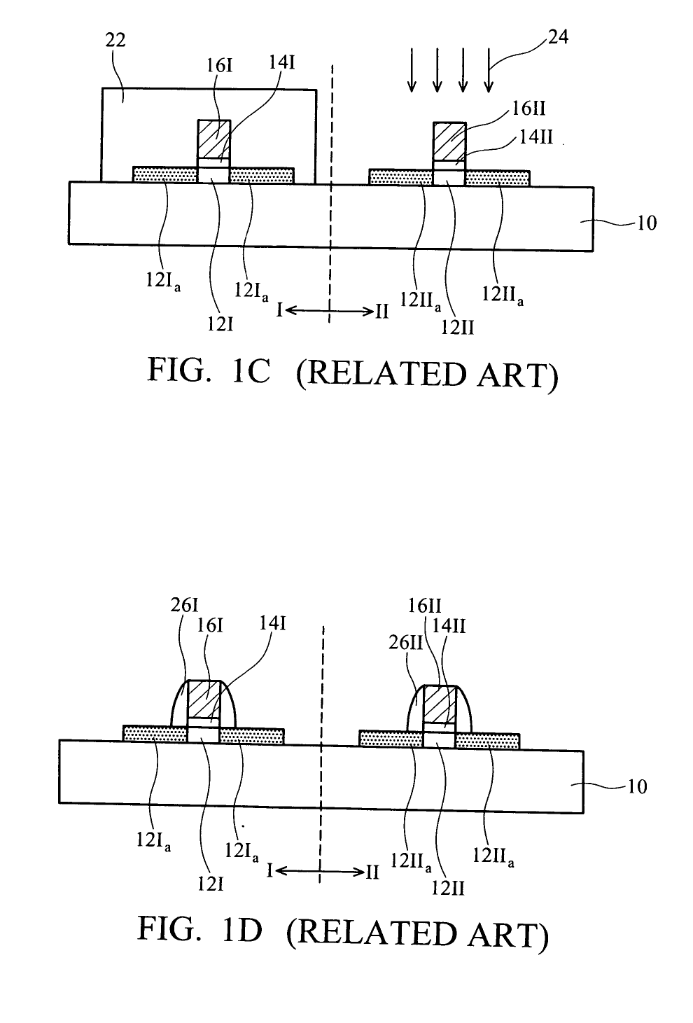

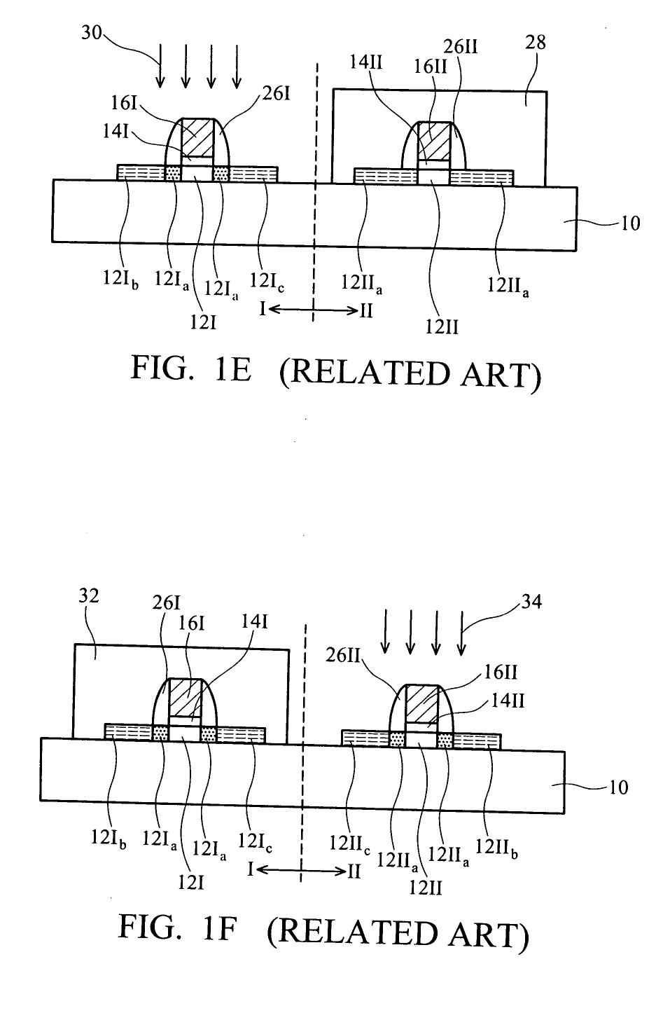

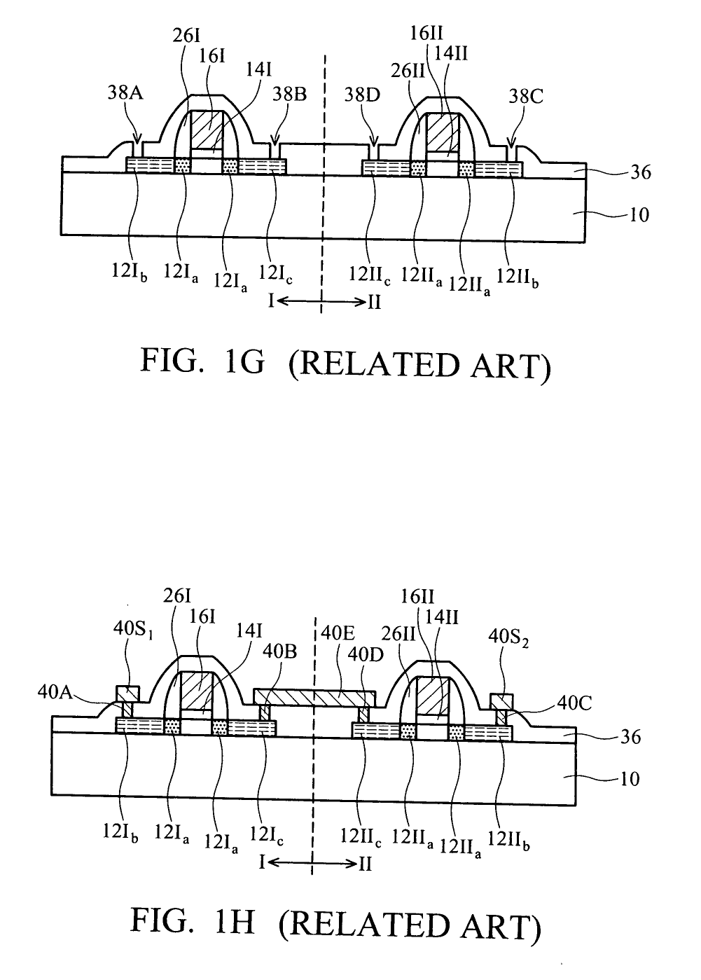

### DETAILED DESCRIPTION

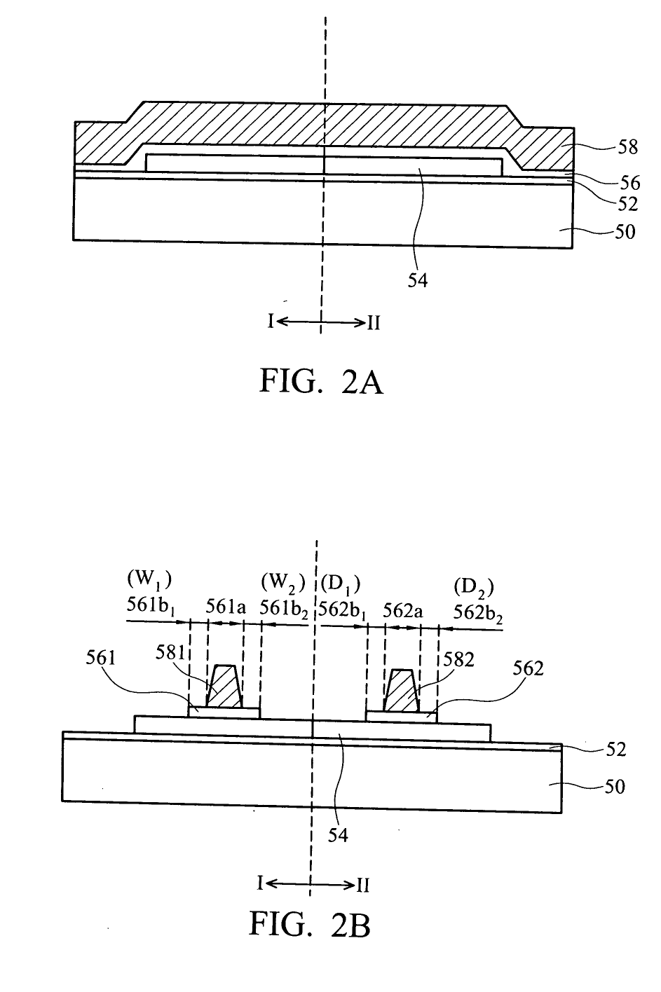

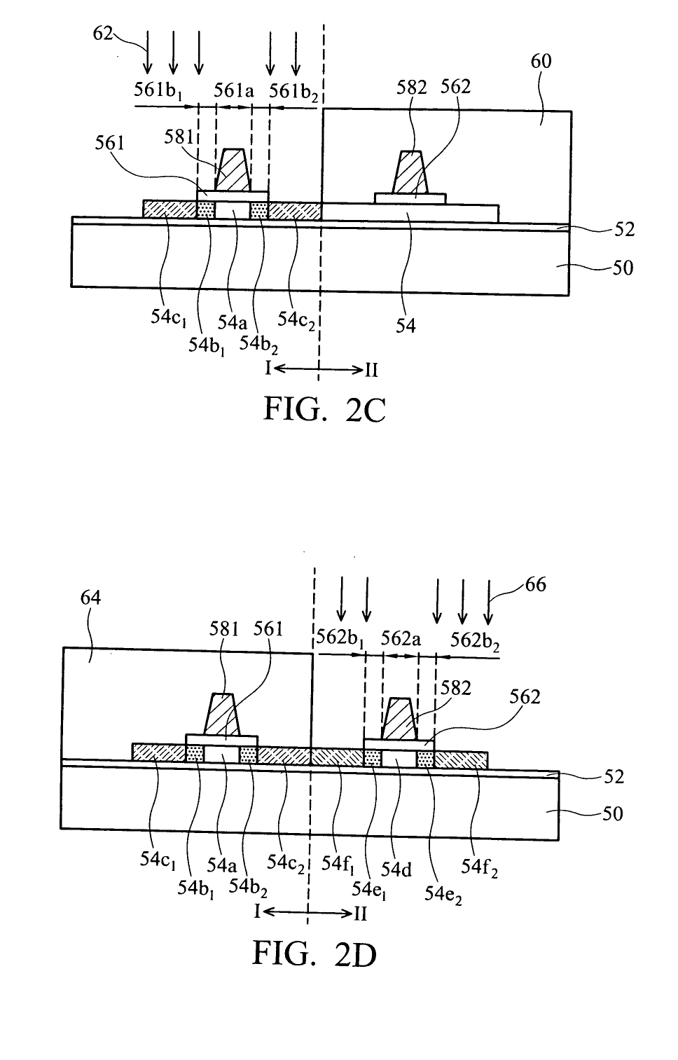

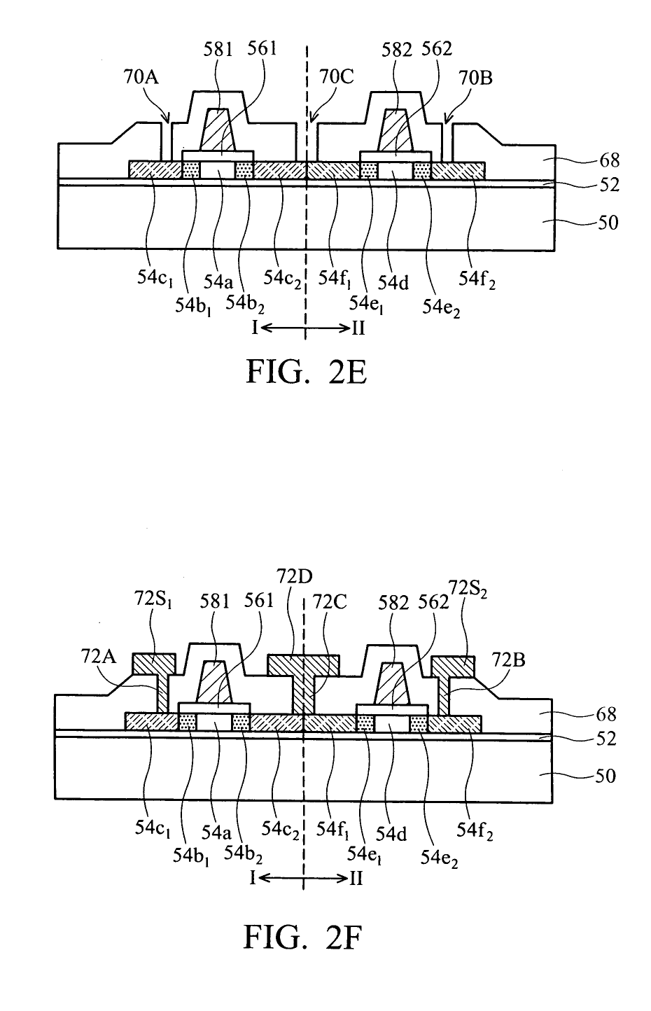

FIGS. 2A˜2F are cross sections of an embodiment of a method for forming serially connected polysilicon TFTs.

In FIG. 2A, a substrate 50 is provided with an N-type TFT region I and a P-type TFT II. A buffer layer 52 and an island-shaped active layer 54 are sequentially formed on the substrate 50. According to various embodiments, the substrate 50 is a transparent substrate, such as, a glass substrate. The buffer layer 52 is a dielectric layer, such as, a silicon nitride layer, for enhancing adhesion between the active layer 54 and the substrate 50. The active layer 54 can be a semiconductor layer such as a polysilicon layer, simultaneously covering the N-type TFT region I and the P-type TFT II.

The active layer 54 can be formed, for example, by low temperature polycrystalline silicon (LTPS) process in which an amorphous silicon layer is first formed on the buffer layer 52 and the amorphous silicon layer is then transformed into a polysilicon layer by annealing or excimer laser annealing (ELA), but is not limited thereto.

Next, an insulating layer 56 and a first conductive layer 58 are sequentially formed on the active layer 54. According to various embodiments, the insulating layer 56 may comprise silicon oxide, silicon nitride, silicon oxynitride or a stacked layer formed by combinations of the described material. The first conductive layer 58 can be a metal layer or a polysilicon layer.

In FIG. 2B, a dry etching using a patterned photoresist layer as an etch mask to define the conductive layer 58 to a first gate electrode 581 and a second gate electrode 582 is performed. A plasma etching or a reactive plasma etching using gas mixtures comprising oxygen-containing gases and chlorine-containing gases is then performed. As the conductive layer 58 is etched, the flow rate of the chlorine-containing gases is gradually increased, even simply using chlorine-containing gases. The oxygen-containing gases are then added until the insulating layer 56 is exposed. Flow rate of the oxygen-containing gases is gradually increased to expose the first gate electrode 581 and the second gate electrode 582 with taper-shaped profiles and two separate first insulating layer 561 and second insulating layer 562 are then formed in the underlying insulating layer 56. The patterned photoresist layers are then removed. The first gate electrode 581, the second gate electrode 582, the first insulating layer 561, and the second insulating layer 562 can be simultaneously formed in the N-type TFT region I and the P-type TFT II by protruding patterned photoresist layers formed by a photolithography using an attenuated phase shifting mask and a sequential etching process.

The first gate insulating layer 561 in the N-type TFT region I comprises a central region 561a, a first mask region 561b₁ and a second mask region 561b₂. The central region 561a is covered by the bottom portion of the first gate electrode 581 and the first mask region 561b₁ and the second mask region 561b₂ are exposed on both sides of the bottom portion of the first gate electrode 581. The first gate insulating layer 561 also exposes predetermined S/D regions of the active layer 54 of an N-type TFT. According to various embodiments, the first mask region 561b₁ has a lateral length W1 of about 0.1˜2.0 μm and the second mask region 561b₂ has a lateral length W2 of about 0.1˜2.0 μm. The lateral length W1 and the lateral length W2 and symmetry thereof are adjustable according to circuit design. For example, W1 may equal to W2, W1 may not equal to W2 or one of the W1 and W2 may be zero.

The second gate insulating layer 562 in the P-type TFT region II comprises a central region 562a, a first mask region 562b₁ and a second mask region 562b₂. The central region 562a is covered by the bottom portion of the second gate electrode 582 and the first mask region 562b₁ and the second mask region 562b₂ are exposed on both sides of the bottom portion of the second gate electrode 582. The second gate insulating layer 562 exposes predetermined S/D regions of the active layer 54 of a P-type TFT. According to various embodiments, the first mask region 562b₁ has a lateral length D1 of about 0.1˜2.0 μm and the second mask region 562b₂ has a lateral length D2 of about 0.1˜2.0 μm. The lateral length D1 and the lateral length D2 and symmetry thereof are adjustable according to circuit design. For example, D1 may equal to D2, D1 may not equal to D2 or one of the D1 and D2 may be zero.

In FIG. 2C, a first photoresist layer 60 is then formed to cover the P-type TFT region II and an N-type ion implant process 62 is then performed on the P-type TFT region II, using the first photoresist layer 60, and the first mask region 561b₁ and the second mask region 561b₂ as implant masks, forming a undoped region 54a, two N⁻ doped regions 54b₁, 54b₂, and two N⁺ doped regions 54c₁, 54c₂ in the active layer 54 of the N-type TFT region I. The undoped region 54a is formed under the central region 561a, serving as a channel region. The first and second N⁻ doped regions 54b₁, 54b₂ are correspondingly formed under the first and second mask regions 561b₁, 561b₂, serving as LDD regions. The first and second N⁺ doped regions 54c₁, 54c₂ are exposed on both sides of the bottom portion of the first gate insulating layer 561, serving as S/D diffusion regions. According to various embodiments, doping concentrations in the first and second N⁻ doped region 54b₁, 54b₂ are about 1×10¹²˜1×10¹⁴ atom/cm² and doping concentrations in the first and second N⁺ doped region 54c₁, 54c₁ are about 1×10¹⁴˜1×10¹⁶ atom/cm². Thus, an N-type TFT is formed and the first photoresist layer 60 is then removed.

In FIG. 2D, a second photoresist layer 64 is formed to cover the N-type TFT region I and a P-type ion implantation process 66 is then performed on the P-type TFT region II, using the second photoresist layer 64 and the mask regions 562b₁, 562b₂ as implant masks, to form a undoped region 54d, two P⁻ doped regions 54e₁, 54e₂, and two P⁺ doped regions 54f₁, 54f₂ in the active layer 54 in the P-type TFT region II. The undoped region 54d is formed under the central region 562a, serving as a channel region. The first and second P⁻ doped regions 54f₁, 54f₂ are correspondingly formed under the first and second mask regions 562b₁, 562b₂, serving as LDD regions. The first and second P⁺ doped regions 54f₁, 54f₂ are exposed on both sides of the bottom portion of the first gate insulating layer 562, serving as S/D diffusion regions. According to various embodiments, doping concentrations in the first and second P⁻ doped region 54e₁, 54e₂ are about 1×10¹²˜1×10¹⁴ atom/cm² and doping concentrations in the first and second P⁺ doped region 54f₁, 54f₁ are about 1×10¹⁴˜1×10¹⁶ atom/cm². Thus, a P-type TFT is substantially formed and the second photoresist layer 64 is then removed.

In FIG. 2E, an interlayer dielectric layer 68 is formed on the N-type TFT and the P-type TFT. A first contact hole 70A, a second contact hole 70B and a third contact hole 70C are then formed in the interlayer dielectric layer 68 via sequential photolithography and etching. The first contact hole 70A exposes the N⁺ doped region 54C₁, the second contact hole 70B exposes the P⁺ doped region 54f₂ and the third contact hole 70C exposes an N/P junction of the N⁺ doped region 54C₂ and the P⁺ doped region 54f₁. Noted that amount and profile of the third contact hole 70C is not limited, but size of the third contact hole 70C must cross the depletion region formed at the N/P junction. According to various embodiments, diameter of the third contact hole is of about 3˜5 μm.

In FIG. 2F, a plurality of contact plugs 72A, 72B, 72C, and a first source conductive layer 72S₁, a second source conducting layer 72S₂ and a drain conducting layer 72D are formed by sequential deposition, photolithography and etching of an second conductive layer. The second conductive layer filled in the first contact hole 70A serves as the first contact plug 72A, electrically connecting the first source conducting layer 72S₁ with the N⁺ doped region 54C₁. The second conductive layer filled in the second contact hole 70B serves as the second contact plug 72B, electrically connecting the second source conducting layer 72S₂ with the P⁺ doped region 54f₂. The second conductive layer filled in the third contact hole 72C serves as the third contact plug 72C and conductive carriers from both sides of the N⁺ doped region 54C₂ and the P+ type doped region 54f₁ can thus be electrically conducted by the drain conductive layer 72D and the third contact plug 72C.

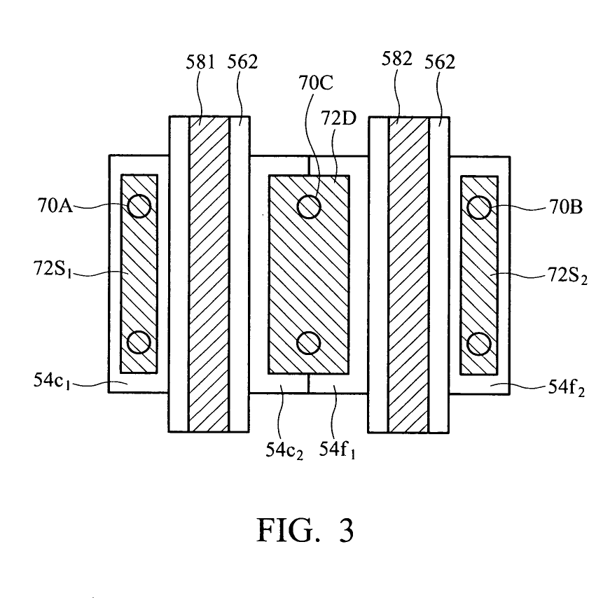

FIG. 3 is a schematic layout of a series structure of polysilicon TFTs according an embodiment. In some embodiments, there is no need to fabricate separate active layers and at least one third contact hole 70C is formed over the N/P junction of the N⁺ doped region 54C₂ and the P⁺ type doped region 54f₁. Moreover, the size of the third contact hole 70 is larger the than the depletion region formed at the N/P junction, thus achieving the same electrical performances as conventionally designed circuits. In addition, this layout may reduce conductive line areas and increase display resolution and simplify fabrication thereof.

Compared to the conventional method, the series structure of N-type TFT and P-type TFT of some embodiments has the following potential advantages.

First, only a single active layer 54 is required and the third contact hole 70C is formed at the N/P junction of the N⁺ doped region 54C₂ and the P⁺ type doped region 54f₁. Conductive carriers in the N⁺ doped region 54C₂ in one end are electrically conducted to the P⁺ type doped region 54f₁ at the other end, without passing through the depletion region formed at the N/P junction, thus achieving the conventional same electrical performances as usual.

Second, the required amount and surface area of the contact holes 70C and the active layers 54 may be reduced, thus also potentially reducing conductive line areas, increasing display resolution and simplifying fabrication steps thereof. This serially connected TFTs provide better pixel resolution of an AMLCD especially when applied to highly integrated circuit designs such as digital analog converters (DAC).

Third, lateral length W1, W2, D1 and D2 of the mask regions 561b₁, 561b₂, 562b₁ and 562b₂ of the first and second gate insulating layer 561 and 562 are controlled by adjusting etching parameters, thus precisely controlling positions of the LDD regions to meet electrical demands of N-type and P-type TFTs.

Fourth, no additional photo mask or spacers are required for defining LDD region patterns, thus reducing position variation due to photo misalignments and provides precise controls of the location of LDD regions.

Fifth, an ion implantation step is reduced, thus potentially simplifying the fabrication steps and lowering costs thereof. In addition, product yields and fabrication speed may also be improved, thereby achieving demands of massive production.

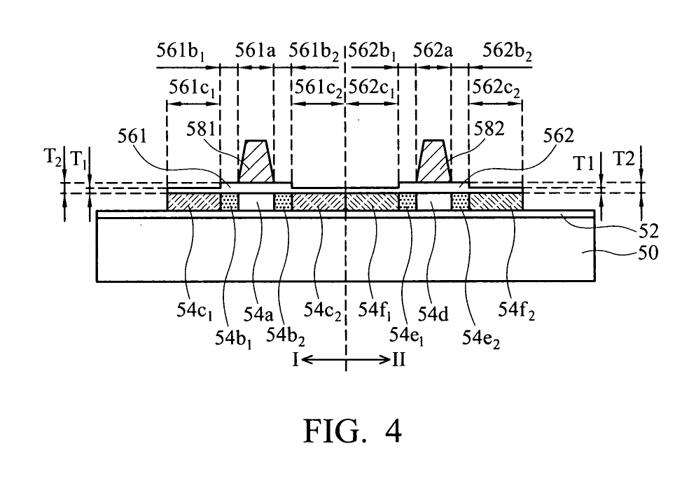

FIG. 4 is another embodiment of a serially connected polysilicon TFTs.

Characteristics of the serially connected polysilicon TFTs as shown in FIG. 4 are substantially the same as that of previously described and identical portions therebetween are not described again here, for simplicity.

In the N-type TFT region I, the first gate insulting layer 561 further comprises a first extension region 561c₁ and a second extension region 561c₂. The first extension region 561c₁ is disposed on the left side of the first mask region 561b₁, covering the first N⁺ doped region 54C₁, and the second extension region 561c₂ is disposed on the right side of the second mask region 561b₂, covering the second N⁺ doped region 54C₂. Particularly, a thickness T1 of the first extension region 561c₁ is less than a thickness T2 of the first mask region 561b₁ and the thickness T1 of the second extension region 561C₂ is less than the thickness T2 of the second mask region 561b₂. As shown in FIG. 4, the underlying polysilicon material is protected by the extension regions 561c₁ and 561c₂, without impacting the doping concentration in the heavily doped regions. Therefore, thicker mask regions 561b₁, 561b₂ can be used as implant masks when forming LDD regions. The LDD regions and the S/D regions can be simultaneously fabricated by single ion implantation incorporating implant energy and dosage adjustments.

Similarly, in the P-type TFT II, the second gate insulting layer 562 further comprises a first extension region 562c₁ and a second extension region 562c₂. The first extension region 562c₁ is disposed on the left side of the first mask region 562b₁, covering the first P⁺ doped region 54f₁, and the second extension region 562c₂ is disposed on the right side of the second mask region 562b₂, covering the second P⁺ doped region 54f₂. Particularly, a thickness T1 of the first extension region 562c₁ is less than a thickness T2 of the first mask region 562b₁ and the thickness T1 of the second extension region 562c₂ is less than the thickness T2 of the second mask region 562b₂. Thus, thicker mask regions 562b₁, 562b₂ can be used as implant masks when forming LDD regions. The LDD regions and the S/D regions can be simultaneously fabricated by a single ion implantation incorporating implant energy and dosage adjustments.

An embodiment of a method for forming the serially connected TFTs as shown in FIG. 4 is substantially the same as previously described embodiments, and identical portions are not described here again, for simplicity. The main difference is in etching the insulating layer 56 to form the first gate insulating layer 561 and the second gate insulating layer 562. Proper control of the etching depth is required to form thicknesses T1 of the extension regions 562c₁, 562c₂ and thicknesses T1 of the extension regions 562c₁, 562c₂ to reach a preferred depth. Another difference is the extension regions 562c₁, 562c₂ and mask regions 562b₁, 562b₂ of the first gate insulating layer 561 may comprise the same material, or mask regions 562b₁, 562b₂ may be a stacked layer formed of a first insulating layer and a second insulating layer and the extension regions are formed of the first insulating layer 562C₁, 562C₂. According to various embodiments, the first insulating layer comprises silicon oxide, silicon nitride, silicon oxynitride or combinations thereof, and the second insulating layer preferably comprises silicon oxide, silicon nitride, silicon oxynitride or combinations thereof. Additionally, the insulating layer may be a stacked layer formed by three or more layers to provide thickness differences between the mask regions 562b₁, 562b₂ and the extension regions 562c₁, 562c₂.

The extension regions 562c₁, 562c₂ of the second gate insulating layer 562 and the mask regions 562b₁, 562b₂ may b comprise the same material. Alternatively, mask regions 562b₁, 562b₂ may be stacked layers formed of a first insulating layer and a second insulating layer and the extension regions 562C₁, 562C₂ are formed of the first insulating layer. According to various embodiments, the first and the second insulating layers comprise silicon oxide, silicon nitride, silicon oxynitride or combinations thereof. Additionally, the first and the second insulating layers may be a stacked layer of three or more insulating layers to provide thickness differences between the mask regions 562b₁, 562b₂ and the extension regions 562c₁, 562c₂.

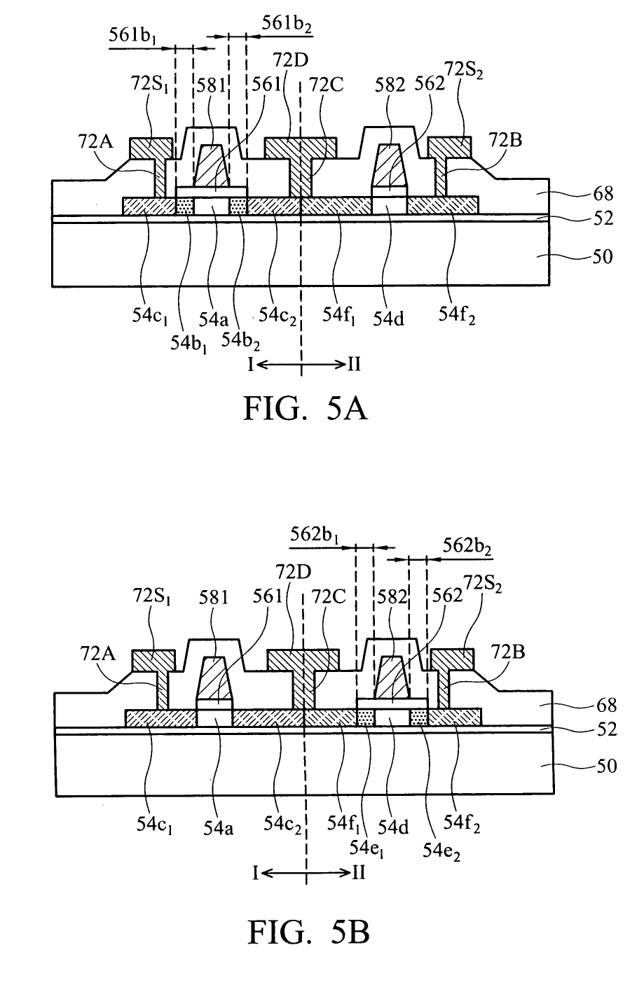

FIGS. 5A˜5B are schematic cross sections of other embodiments of serially connected polysilicon TFTs.

Characteristics of the serially connected polysilicon TFT as show in FIGS. 5A and 5B are substantially the same as previously described embodiments and identical portions therebetween are not described again here. The main difference therebetween is the design of the mask regions of the gate insulating layer only applied to either the N-type TFT region I or the P-type TFT region II.

In FIG. 5A, the first gate insulating layer 561 in the N-type TFT region I comprises first and second mask region 561b₁, 561b₂ for defining size, location and symmetry of the LDD regions. No mask regions are formed in the second gate insulating layer 562 of the P-type TFT region II, thereby forming no LDD regions in the active region (referring to the doped regions 54d, 54f₁, and 54f₂). In FIG. 5B, the second gate insulating layer 562 in the N-type TFT region II comprises first and second mask regions 562b₁, 562b₂ for defining sizes, location and symmetry of the LDD regions. No mask regions are formed in the first gate insulating layer 561 of the N-type TFT region I. Thus, no LDD regions are formed in the active region (referring to the doped regions 54a, 54c₁, and 54c₂). Embodiments of methods for forming the serially connected TFTs as shown in FIGS. 5A and 5B are substantially the same as previously described embodiments but are not described here again, for simplicity.

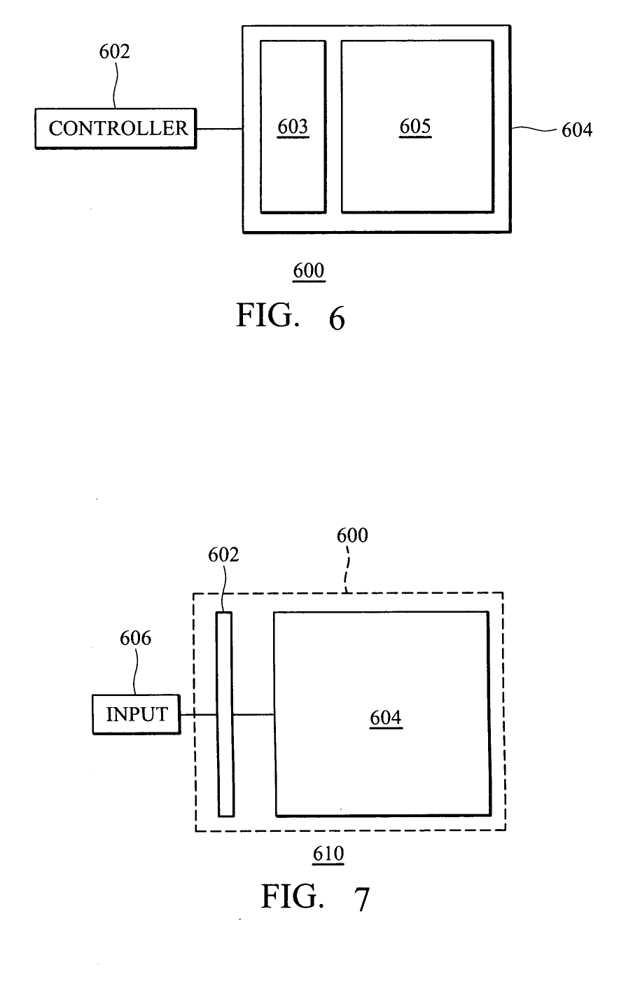

FIG. 6 shows a display device 600 (e.g., a flat panel display module) comprising a display panel 604 incorporating a display area 605 and a driving area 603 which comprise a thin film transistor structure such as that shown in FIGS. 2F, 4, 5A and 5B. Display panel 604 can be coupled to a controller 602 and may comprise plasma, light emitting diode (LED), liquid crystal (LC) or electroluminescent (EL) display elements. The controller 602 can comprise source and gate driving circuits (not shown), controlling the display panel 604 for operation of the display device 600. The display panel 604 may comprise electroluminescent display elements of the type such as OLED, plasma, etc. display elements, or light filtering display elements of the type such as liquid crystal display elements.

FIG. 7 is a schematic diagram illustrating an electronic device incorporating the display device 600 shown in FIG. 6. An image data source 606 is coupled to the controller 602 of the display device 600 shown in FIG. 6 to form an electronic device 610. The image data source 606 can include a processor or the like to input image data to the controller 602 to render an image. The electronic device 610 may be a portable device such as a PDA, notebook computer, tablet computer, cellular phone, or a display monitor device, or a non-portable device such as a desktop computer.

While the present invention has been described by way of example and in terms of various embodiments, it is to be understood that the present invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A thin film transistor structure, comprising:
a first TFT of a first type having a first doped region of a first type;
a second TFT of a second type having a second doped region of a second type different from the first type, wherein the first region is contiguous to the second region.

2. The structure as in claim 1, wherein the first TFT and the second TFT share a common active layer comprising the first doped region and second doped region.

3. The structure as in claim 1, wherein a depletion region is formed at a junction between the first doped region and the second doped region.

4. The structure as in claim 3, further comprising a conductive layer electrically connected to the depletion region.

5. The structure as in claim 1, wherein comprising a contact hole exposing the depletion region at the junction of the first TFT and second TFT.

6. The structure as in claim 5, wherein the contact hole has a larger size than that of the depletion region formed at the junction.

7. The structure as in claim 5, wherein the contact hole has a size of about 3˜5 μm.

8. The structure as in claim 1, wherein the first doped region and the second doped region respectively has a lightly doped region with a doping concentration of about 1*10¹²˜1*10¹⁴ atom/cm² and a heavily doped region with a doping concentration of about 1*10¹⁴˜1*10¹⁶ atom/cm².

9. The structure as in claim 1, wherein the first doped region has a lightly doped region with a doping concentration of about 1*10¹²˜1*10¹⁴ atom/cm² and the first doped region and the second doped region respectively has a heavily doped region with a doping concentration of about 1*10¹⁴˜1*10¹⁶ atom/cm².

10. The structure as in claim 1, wherein the first type TFT is an N-type TFT and the second type TFT is a P-type TFT.

11. The structure as in claim 1, wherein the first TFT comprising a first gate insulating layer further comprises:
a central region, covering a first channel region of the common active layer;
a mask region, covering a first lightly doped region of the common active layer.

12. The structure as in claim 11, wherein the first gate insulating layer further comprises an extension region, extending from and covering the mask region in the first gate insulating layer to a first heavily doped region of the active layer, covering thereof, and the extension region has a thickness less than that of the mask region.

13. The structure as in claim 1, wherein the second gate insulating layer further comprises:
a central region, covering a second channel region of the common active layer;
a mask region, covering a second type lightly doped region of the common active layer.

14. The structure as in claim 13, wherein the second gate insulating layer further comprises an extension region, extending from and covering the mask region in the second gate insulating layer to a second heavily doped region of the active layer, covering thereof, and the extension region has a thickness less than that of the mask region.

15. A method for fabricating a thin film transistor structure, comprising:
forming a first TFT of a first type having a first doped region of a first type;
forming a second TFT of a second type having a second doped region of a second type different from the first type, wherein the first region is formed contiguous to the second region.

16. The method of claim 15, wherein the forming of the first TFT and the forming of the second TFT comprise providing a common active layer, and forming the first doped region and second doped region in the common active layer.

17. The method of claim 15, further comprising forming a contact hole has a larger size than that of the depletion region formed at the junction.

18. The method of claim 17, wherein the contact hole has a size of about 3˜5 μm.

19. A display device, comprising:
a display panel comprising a thin film transistor structure of claim 1; and
a controller operatively coupled to the display panel to control the display panel to render an image in accordance with an image date.

20. An electronic device, comprising:
a display device of claim 19; and
an image data source coupled to the controller of the display device to provide the image data to the display device to render an image.
